(19) United States
(12) Patent Application Publication
(10) Pub. No.: US 2003/0085470 A1
(43) Pub. Date: May 8, 2003

(54) Semiconductor device and method of manufacturing the same

(75) Inventor: Masahiko Hasunuma, Yokohama-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/254,669

(22) Filed: Sep. 26, 2002

(30) Foreign Application Priority Data
Sep. 28, 2001 (JP) 2001-301364

(51) Int. Cl. H01L 23/48

(52) U.S. Cl. 257/774

(57) ABSTRACT

A semiconductor device includes an insulating film disposed on or above a semiconductor substrate, and an interconnection portion disposed on the insulating film. The interconnection portion includes a barrier film disposed on the insulating film, and a conductive layer disposed on the barrier film. The barrier film consists essentially of an alloy of a first material and Ta. The first material is at least one element selected from the group consisting of Group IVa elements, Group Va elements excluding Ta, and Group VIa elements. The conductive layer contains Cu or Ag as a major element.

### CROSS-REFERENCE TO RELATED APPLICATIONS

This application is based upon and claims the benefit of priority from the prior Japanese Patent Application No. 2001-301364, Sep. 28, 2001, the entire contents of which are incorporated herein by reference.

### BACKGROUND OF THE INVENTION

1. Field of the Invention

The present invention relates to a semiconductor device and a method of manufacturing the same and, more particularly, to a semiconductor device having an interconnection portion with a metal barrier film and a method of manufacturing the same.

2. Description of the Related Art

Conventionally, Al interconnections are often used as LSI interconnections. In recent years, Cu interconnections have been used in terms of improvement of RC (Resistance X Capacitance) delay and EM (electromigration) resistance. Cu is difficult to process by RIE (Reactive Ion Etching) because few Cu compounds have a high vapor pressure. For this reason, to form a Cu interconnection, a damascene process that forms a Cu interconnection without using RIE is mainly used.

According to the damascene process, a metal film is deposited on the entire surface in order to fill an interconnection groove formed in an interlayer dielectric film in advance. Then, an excessive metal film outside the interconnection groove is removed by CMP (Chemical Mechanical Polishing). In this manner, an interconnection (damascene interconnection) is formed from the remainder of the metal film left in the interconnection groove.

Alternatively, an interconnection and via plug can be formed simultaneously. In this case, an interconnection groove and via hole are formed in an interlayer dielectric film in advance, and are filled with a metal film at once. This process is called a dual damascene process (DD process).

When a Cu interconnection is to be formed by a damascene process, a Cu film is used as an interconnection metal film. Cu tends to diffuse in an interlayer dielectric film. Hence, Cu may diffuse to, e.g., a Si substrate, thereby degrading the transistor characteristics.

In view of this, when a Cu interconnection is to be formed by a damascene process, before a Cu film is deposited, a metal barrier film for preventing Cu diffusion is formed on the inner surface of the interconnection groove by sputtering. In the case of a DD process, a barrier film must be formed also on the inner surface of the via hole.

Currently, a Ta film, a TaN film, or a multilayered film of them (Ta film/TaN film) is generally used as a barrier film. A barrier film must have Cu diffusion barrier properties and be able to obtain a low electrical resistance with less fluctuation.

### BRIEF SUMMARY OF THE INVENTION

According to a first aspect of the present invention, there is provided a semiconductor device comprising:

an insulating film disposed on or above a semiconductor substrate; and

an interconnection portion disposed on the insulating film,

the interconnection portion comprising

a barrier film disposed on the insulating film, the barrier film including an alloy of a first material and Ta, the first material being at least one element selected from the group consisting of Group IVa elements, Group Va elements excluding Ta, and Group VIa elements, and

a conductive layer disposed on the barrier film, the conductive layer containing Cu or Ag as a major element.

According to a second aspect of the present invention, there is provided a semiconductor device manufacturing method comprising:

forming an insulating film on or above a semiconductor substrate;

forming an interconnection groove in a surface of the insulating film;

forming a barrier film to cover an inner surface of the interconnection groove, the barrier film including an alloy of a first material and Ta, and the first material being at least one element selected from the group consisting of Group IVa elements, Group Va elements excluding Ta, and Group VIa elements;

forming a conductive layer on the barrier film to fill the interconnection groove, the conductive layer containing Cu or Ag as a major element; and

removing portions of the barrier film and conductive layer, which are located outside the interconnection groove, to form an interconnection portion comprising remainders of the barrier film and conductive layer in the interconnection groove.

### BRIEF DESCRIPTION OF THE SEVERAL VIEWS OF THE DRAWING

FIGS. 1A to 1E are sectional views showing a method of manufacturing a semiconductor device according to an embodiment of the present invention;

FIG. 2 is a graph showing the relationship between the Nb content and resistivity of a TaNb alloy film;

FIG. 3 is a graph showing the relationship between the Mo content and resistivity of a TaMo alloy film; and

FIG. 4 is a graph showing the relationship between the Nb content and film stress of the TaNb alloy film.

### DETAILED DESCRIPTION OF THE INVENTION

In the process of the developing the present invention, the inventor studied a conventional barrier film formed of a Ta film, a TaN film, or a multilayered film of them (Ta film/TaN film), used in Cu interconnections, and arrived at the findings given below.

When a Ta film is formed by a method with rapid cooling, such as sputtering film formation, the crystal structure becomes β-Ta (tetragonal system), thereby providing a film with a higher resistivity than a film having an α-Ta (bcc (body-centered cubic lattice)) crystal structure. Furthermore, when these two types of crystal structures are mixed, since the mixing ratio has a low reproducibility, variations are increased in resistivity of the barrier film. Such variations in resistivity of the barrier film cause variations in resistance of the entire interconnection and variations in resistance of the via plug. Hence, interconnection design becomes difficult.

In addition, when these two types of crystal structures are mixed, the stress of the barrier film increases. This is a major factor that causes film peeling during a CMP process or a multilayer interconnection process.

As a countermeasure against these problems, a method of forming a Ta film on a TaN film and converting the Ta film to have a a-Ta crystal structure is proposed. When, however, such a multilayered film (Ta film/TaN film) is used as a barrier film, the effective resistance of the interconnection increases undesirably.

One reason for this increase is the high resistivity of the TaN film itself. Another reason is as follows. When a multilayered film is used, the thickness of the barrier film increases accordingly. Then, the volume of the Cu interconnection that occupies the interior of the interconnection groove decreases. From these reasons, to decrease the thickness and resistivity of the barrier film is an urgent necessity.

As described above, the Cu interconnection forming method in accordance with the conventional damascene process increases the resistivity and stress of the barrier film. Consequently, the interconnection resistance increases, and film peeling is caused.

Embodiments of the present invention achieved on the basis of the findings given above will now be described with reference to the accompanying drawings.

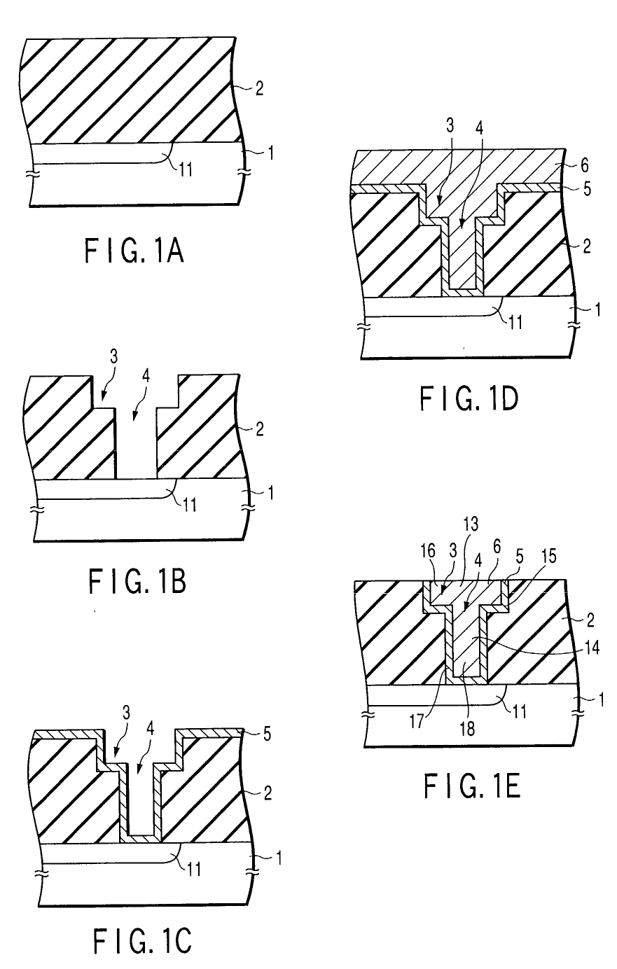

FIGS. 1A to 1E are sectional views showing a method of manufacturing a semiconductor device according to an embodiment of the present invention. FIG. 1E shows a state wherein the interconnection portion of this semiconductor device is completed.

As shown in FIG. 1E, for example, a MOS transistor (only one source/drain diffusion layer 11 of the MOS transistor is shown in FIG. 1E) is formed in the active region of a semiconductor substrate 1 such as a Si wafer. An insulating film 2 is disposed on (or above) the substrate 1. In order to improve the operating speed, for example, the insulating film 2 is formed of a Low-k material (material with a low dielectric constant), e.g., silicon oxide containing an organic component. If signal delay can be suppressed, a fluorine-doped silicon oxide film (FSG) may be used as the insulating film 2.

An interconnection groove 3 is formed in the surface of the insulating film 2. A via hole 4 (contact hole) is formed in the insulating film 2 to extend from the interconnection groove 3 to the source/drain diffusion layer 11. An interconnection portion 13 and via plug 14 are buried in the interconnection groove 3 and via hole 4, respectively. In other words, the source/drain diffusion layer 11 and interconnection portion 13 are electrically connected to each other through the via plug 14.

The interconnection portion 13 is formed of a barrier film 15 and conductive layer 16. The barrier film 15 is disposed on the insulating film 2 to cover the inner surface of the interconnection groove 3. The conductive layer 16 is disposed on the barrier film 15. The via plug 14 is formed of a barrier film 17 and conductive layer 18. The barrier film 17 is disposed on the insulating film 2 to cover the inner surface of the via hole 4. The conductive layer 18 is surrounded by the barrier film 17.

The barrier films 15 and 17 of the interconnection portion 13 and via plug 14 are integrally formed of an alloy of the following first material and Ta. The barrier films 15 and 17 have thicknesses of 3 to 30 nm and preferably 5 to 20 nm. The first material is formed of at least one element selected from the group consisting of Group IVa elements, Group Va elements excluding Ta, and Group VIa elements. Preferably, the first material is formed of at least one element selected from the group consisting of Nb, Mo, W, and Ti. Where the first material is formed of an element selected from the group consisting of Nb, Mo, W, and Ti, the contents of the first material in the barrier films 15 and 17 are preferably set to be 20 to 90 at % in the case of Nb, 5 to 90 at % in the case of Mo, 10 to 90 at % in the case of W, and 15 to 90 at % in the case of Ti.

The conductive layers 16 and 18 of the interconnection portion 13 and via plug 14 are integrally formed of a material containing Cu or Ag as the major element (50 at % or more). The thickness of the conductive layer 16 of the interconnection portion 13 and the diameter of the conductive layer 18 of the via plug 14 are determined in accordance with a used design rule. An example of the material used in the conductive layers 16 and 18 and containing Cu as the major element can include Cu, Cu—Ag, Cu—Mg, Cu—Al, Cu—Au, Cu—Pt, Cu—Zr, and Cu—Ti.

In the structure shown in FIG. 1E, the via plug 14 electrically connects the source/drain diffusion layer 11 of the active region and the interconnection portion 13 of the Si substrate 1. Alternatively, the via plug 14 may be used to connect upper and lower two interconnection portions 13 to each other.

A method of manufacturing the semiconductor device will be described with reference to FIGS. 1A to 1E by way of an example using a DD process.

First, as shown in FIG. 1A, an insulating film 2 with a thickness of 1 μm and made of a material with a low dielectric constant, e.g., silicon oxide containing an organic component, is formed on a Si substrate 1. Subsequently, as shown in FIG. 1B, an interconnection groove 3 and via hole 4 are formed in the insulating film 2. The width of the interconnection groove 3 is, e.g., 0.25 μm, and the depth of the interconnection groove 3 is, e.g., 0.25 μm. Of the interconnection groove 3 and via hole 4, either one can be formed first.

As shown in FIG. 1C, a barrier film 5 is formed on the insulating film 2 to cover the side and bottom surfaces of the interconnection groove 3 and via hole 4. For example, the barrier film 5 is formed of a TaNb alloy film with a thickness of 30 nm. The barrier film 5 is preferably formed at room temperature in a high-vacuum atmosphere by bias-assisted sputtering. As the target used for formation of the barrier film 5, a TaNb alloy target is preferable. Alternatively, a target having mosaic arrays of Ta and Nb portions may be used instead. Furthermore, a powder-sintered target formed by mixing and sintering Ta powder and Nb powder may be used instead.

As shown in FIG. 1D, a conductive layer 6 is formed to fill the interconnection groove 3 and via hole 4. For example, the conductive layer 6 is formed of a Cu layer with a thickness of 600 nm. The conductive layer 6 can be formed by the following method. Specifically, with the high-vacuum atmosphere being maintained, a first conductive film (Cu film) with a thickness of 80 nm is formed on the barrier film 5 by bias-assisted sputtering. Then, a second conductive film (Cu film) is formed on the first conductive film by electro-plating. The first conductive film serves as a seed layer when forming the second conductive film. Thus, the conductive layer 6 formed of the first and second conductive films is formed on the barrier film 5.

Subsequently, the entire portion of the Si substrate 1 including the barrier film 5 and conductive layer 6 is heat-treated at a temperature of 350 to 750° C., in an atmosphere of, e.g., a forming gas. Then, as shown in FIG. 1E, those portions of the conductive layer 6 and barrier film 5 which are located outside the interconnection groove 3 and via hole 4 are removed by CMP. Hence, the interconnection portion 13 and via plug 14 can be formed by the DD process from the remainders of the barrier film 5 and conductive layer 6 in the interconnection groove 3 and via hole 4.

More specifically, according to the manufacturing method described above, the barrier film 5 is a product prepared by a process, which includes forming the barrier film 5 on the insulating film 2 by sputtering, and heat-treating the barrier film 5 at a temperature of 350 to 750° C. Alternatively, as will be described later, the barrier film 5 may be a product prepared by a process, which includes forming the barrier film 5 on the insulating film 2 by sputtering while heating the semiconductor substrate 1 to a temperature of 150 to 350° C.

According to the above manufacturing method, the conductive layer (Cu layer) 6 is a product prepared by a process, which includes forming the first conductive film (Cu film) on the barrier film 5 by sputtering, and forming the second conductive film (Cu film) on the first conductive film by electro-plating.

In the steps shown in FIGS. 1C and 1D, the barrier film 5 and the first conductive film are preferably formed by bias-assisted sputtering with high anisotropy. Then, the inner surface of the interconnection groove 3 and that of the via hole 4 having a high aspect ratio (depth/width) can be easily covered by the barrier film 5 and the first conductive film. Regarding this, in an experiment using bias-assisted sputtering with high anisotropy, the inner surfaces of the interconnection groove 3 and via hole 4 were covered by a TaNb alloy film and Cu film. As a result, good coverage was obtained both in a case where the aspect ratio of the interconnection groove 3 was 1 and that of the via hole 4 was 2.0, and in a case where the aspect ratio of the interconnection groove 3 was 1.5 and that of the via hole 4 was 2.0.

In an experiment, a TaNb alloy film formed under the same conditions as those for the barrier film 5 was heat-treated at 300° C. The heat-treated TaNb alloy film was examined by X-ray diffraction. As a result, the TaNb alloy film had an α-Ta crystal structure (body-centered cubic structure) and did not substantially have a β-Ta crystal structure (tetragonal system structure). This means that a low-resistance barrier film 5 can be obtained with less fluctuation.

In an experiment, how the resistivity of the TaNb alloy film as the barrier film 5 changed was studied in the method described above by changing the Nb content in the TaNb alloy film. The resistivity of the TaNb alloy film was calculated from the measurement result of the effective resistance of the DD interconnection portion 13 (barrier film 5+conductive layer 6). As the Nb content, 0.5 at %, 10 at %, 20 at %, 40 at %, 60 at %, 80 at %, 85 at %, 90 at %, 95 at %, and 100 at % were used. Regarding the temperature of heat treatment, a case with 350° C. treatment and a case with no heat treatment (as depo) were studied in addition to the case of 300° C. described above.

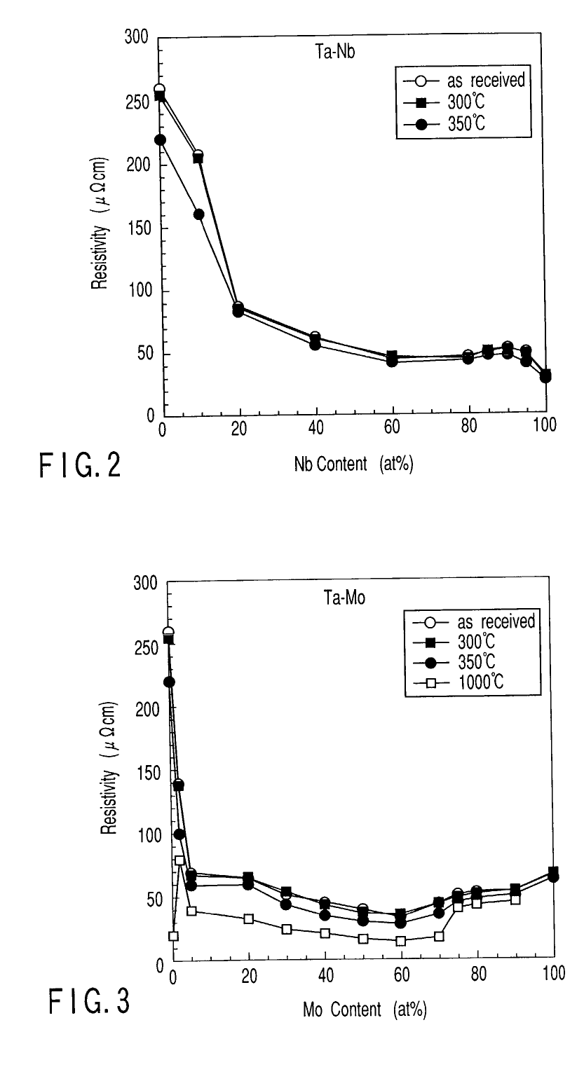

FIG. 2 is a graph showing the relationship between the Nb content and resistivity of the TaNb alloy film, obtained by this experiment. As shown in FIG. 2, the resistivity decreased when the Nb content was 10 at % or more. The resistivity decreased largely when the Nb content was 20 at % or more. Furthermore, regarding a decrease in resistance of the interconnection, a preferable result was obtained when the Nb content was 40 at % or more. The robustness (stability) increased when the Nb content was 20 at % or more.

Regarding the temperature of heat treatment, at 300° C., the same resistivity as that in the case of as received was obtained. With heat treatment of 350° C. or more, a resistivity lower than that of the case of as received was obtained. Furthermore, when heat treatment was performed not after but simultaneously with formation of the barrier film (heating film formation), the resistivity also decreased. In this case, due to the high energy of sputtered particles, when the substrate temperature was 150° C. or more, the resistivity of the barrier film decreased. When the substrate temperature was held at a high temperature higher than 750° C., degradation in device characteristics was confirmed. Therefore, the temperature of heat treatment is preferably set to 700° C. or less.

As described above, as the barrier film 5, a TaMo alloy film, a TaW alloy film, a TaTi alloy film, or the like can also be used. Accordingly, the relationship between the composition and resistivity of these alloy films was also studied by experiments.

FIG. 3 is a graph showing the relationship between the Mo content and resistivity of the TaMo alloy film. As shown in FIG. 3, the resistivity decreased when the Mo content was 2.5 at % or more. The resistivity decreased largely when the Mo content was 5 at % or more. In other words, with the TaMo alloy film, the same result as that obtained with the TaNb alloy film was obtained. The robustness (stability) increased when the Mo content was 5 at % or more.

With a TaW alloy film, the resistivity decreased largely when the W content was 10 at % or more. With a TaTi alloy film, the resistivity decreased largely when the Ti content was 15 at % or more.

Regarding the temperature of heat treatment after film formation, with the TaMo alloy film, TaW alloy film, or TaTi alloy film, the resistivity decreased at 350° C. or more. When heat treatment (heating film formation) was performed simultaneously with film formation, the resistivity of the barrier film decreased when the substrate temperature was 150° C. or more, in the same manner as with the TaNb alloy film.

In an experiment, how the crystal structure changed in accordance with the Nb and Mo contents in the TaNb alloy film and TaMo alloy film, respectively, was studied. In this experiment, the ratio of the crystal structure (Iα) of the body-centered cubic lattice to the crystal structure (Iβ) of the tetragonal system was measured. The ratio Iα/Ib of the two crystal structures was obtained from the peak strength ratio of α-Ta (110) to β-Ta (002) as the results of XRD measurement.

TABLE 1 shows the relationship between the crystal structure and Nb content of the TaNb alloy film. TABLE 2 shows the relationship between the crystal structure and Mo content of the TaMo alloy film. From the comparison of TABLES 1 and 2 and FIGS. 2 and 3, the decrease in resistivity was clearly related to a change in crystal structure. The same tendency was observed in the TaW alloy film and TaTi alloy film concerning the W and Ti contents, respectively.

TABLE 1

| Nb | | | | | | | | | | |
|---|---|---|---|---|---|---|---|---|---|---|
| content | 0 | | | | | | | | | |
| (at %) | (pure-Ta) | 10 | 20 | 40 | 60 | 80 | 85 | 90 | 95 | 100 |
| Iα/Iβ | 0 | 1.6 | 20 | 80 | ∞ | ∞ | ∞ | ∞ | ∞ | ∞ |

tABLE 2

| Mb | | | | | | | | | | | | | |
|---|---|---|---|---|---|---|---|---|---|---|---|---|---|
| content | 0 | | | | | | | | | | | | |
| (at %) | (pure-Ta) | 2.5 | 5 | 20 | 30 | 40 | 50 | 60 | 70 | 75 | 80 | 90 | 100 |
| Iα/Iβ | 0 | 25 | 200 | ∞ | ∞ | ∞ | ∞ | ∞ | ∞ | ∞ | ∞ | ∞ | ∞ |

In an experiment, the adhesion properties of the TaNb alloy film as the barrier film 5 and the underlying layer were evaluated in accordance with the m-ELT (modified Edge Lift-off Test). In this experiment, a sample in the state shown in FIG. 1D was coated with an epoxy resin to a thickness of 100 μm, and was baked at 175° C. The sample was diced into squares having a side of about 1 inch. The temperature was gradually decreased to liquid nitrogen temperature. The temperature at which peeling due to thermal stress started was monitored. From the obtained peeling start temperature, the mechanical characteristics (Young's modulus, coefficient of linear expansion, and Poisson ratio) of the epoxy resin, the thickness of the epoxy film, and the like, Kₐₚₚ as the index of interface fracture strength was obtained by the method of E. O. Shaffer II et al (Poly. Sci. & Eng., Vol. 36, (18), 1996, pp. 2375-2381). The adhesion strength of the barrier film and underlaying layer is a significant matter against the CMP process and the thermal stress caused by the resin in the packaging process. From the result of experiment conducted by the present inventor, Kₐₚₚ must be 0.4 MPa (m)^{1/2} or more.

TABLE 3 shows the relationship between the adhesion strength of the TaNb alloy film with respect to the underlying film (SiO₂ film) and the Nb content. Referring to TABLE 3, “0.45 or more” means that the adhesion strength is equal to or more than the measurement upper limit obtained when a 100-μm thick epoxy resin was used. As shown in TABLE 3, from the viewpoint of adhesion strength, the Nb content in the TaNb alloy film was preferably 90 at % or less, and more preferably 85 at % or less.

TABLE 3

| Nb content | 0 | | | | | | | | 100 |
|---|---|---|---|---|---|---|---|---|---|
| (at %) | (pure-Ta) | 10 | 20 | 40 | 80 | 85 | 90 | 95 | (pure-Nb) |
| Kapp | 0.45 or | 0.45 | 0.45 | 0.45 | 0.45 | 0.45 | 0.40 | 0.35 | 0.31 |
| (MPa (m)^{1/2}) | more | or | or | or | or | or | | | |
| | | more | more | more | more | more | | | |

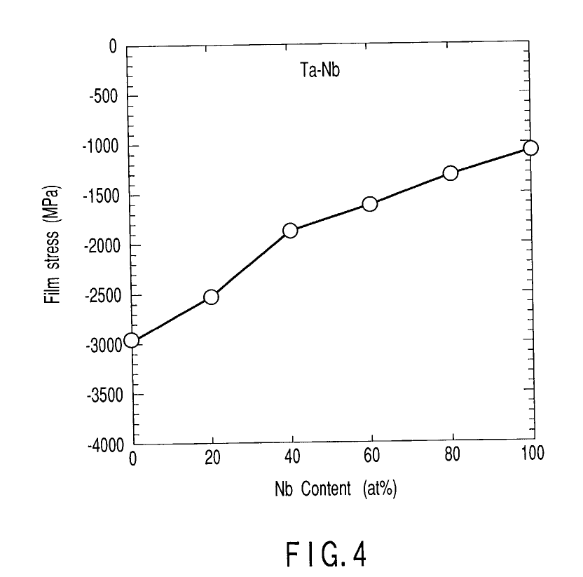

In an experiment using an apparatus that obtains a stress from the warp of a wafer (substrate), the film stress of the TaNb alloy film as the barrier film 5 was measured. FIG. 4 is a graph showing the relationship between the Nb content and film stress of the TaNb alloy film. As shown in FIG. 4, when Nb was contained in the alloy film, the stress was decreased. To decrease the internal stress of the barrier film 5 is important in terms of the adhesion strength and in increasing the stress migration resistance. The internal stress of the barrier film 5 is preferably 2 GPa or less. Accordingly, from the viewpoint of the film stress, the Nb content of the TaNb alloy film was preferably 40 at % or more.

In an experiment, the barrier properties of the TaNb alloy film as the barrier film 5 against Cu were studied. In this experiment, a sample in the state shown in FIG. 1E was left at 450° C. for 100 hours, and the Cu concentration of the insulating film 2 was analyzed. As a result, when the Nb content was in the range of 5 to 90 at % (both inclusive), the Cu concentration (leakage amount) was 1×10¹² atoms/cm² or less. Thus, good barrier properties were obtained.

The experimental results concerning the various characteristics described above clarified the following fact. That is, when the barrier film 5 is a TaNb alloy film, the lower limit of the Nb content is preferably 20 at %, and more preferably 40 at %. The upper limit of the Nb content is preferably 90 at %, and more preferably 85 at %.

Similarly, when the barrier film 5 is a TaMo alloy film, the optimal Mo content is in the range of 5 to 90 at % (both inclusive). When the barrier film 5 is a TaW alloy film, the optimal W content is in the range of 10 to 90 at % (both inclusive). When the barrier film 5 is a TaTi alloy film, the optimal Ti content is in the range of 15 at % and 90 at % (both inclusive).

In an experiment, the relationship between the thickness of the barrier film 5 and the barrier properties of the barrier film 5 against Cu were studied. In this experiment, a target subject in the state shown in FIG. 1E having a barrier film 5 with a predetermined thickness was left at 450° C. for 100 hours. Then, the Cu concentration in the insulating film 2 was analyzed. As a result, when either one of the TaNb alloy film, TaMo alloy film, TaW alloy film, and TaTi alloy film was used as the barrier film 5, as far as the film thickness was 3 nm or more, the Cu concentration (leakage amount) was 1×10¹² atoms/cm² or less, and good barrier properties were obtained. When the thickness of the barrier film 5 increases, the resistance of the whole interconnection increases. Accordingly, the thickness of the barrier film 5 is set within the range of 3 to 30 nm, and preferably 5 to 20 nm.

As a comparative example, an experiment was conducted regarding a case where a pure Ta film was used as the barrier film. In this case, the pure Ta barrier film had good barrier properties and adhesion properties. However, the resistivity of the pure Ta barrier film was about 250 μΩcm, and the resistance did not decrease even with heat treatment at 350° C. The resistivity of the pure Ta film could be decreased to about 50 μΩcm by heat treatment at a temperature higher than 750° C. Heat treatment at a temperature higher than 750° C., however, is not practical because it adversely affects a semiconductor element, e.g., a MOS transistor, which is formed before formation of the interconnection.

In contrast to this, with the barrier film 5 according to the embodiment of the present invention, as described above, the resistance can be decreased by heat treatment at a temperature of 350 to 750° C. (both inclusive). In order to avoid degradation of the element characteristics, it is particularly preferable to perform heat treatment at a temperature of 350 and 700° C. (both inclusive).

As described above, according to this embodiment, when the element such as Nb in a Ta alloy film, i.e., TaNb alloy film, to be used as the barrier film 5 is set to a predetermined proportion, the resistivity and stress of the barrier film 5 can be decreased sufficiently. In addition, when such a barrier film 5 is used, good device characteristics can also be obtained.

The present invention is not limited to the above embodiment. For example, in the above description, to form an alloy film of the barrier film 5, Nb, Mo, W, and Ti are indicated as an example of a material that forms an alloy together with Ta. However, this material suffices if it is at least one material selected from the group consisting of Group IVa elements, Group Va elements excluding Ta, and Group VIa elements. An example of the material that contains Cu, which is to be used in the conductive layer 6 of the interconnection portion and the via plug, as the major element (50 at % or more) can include Cu, Cu—Ag, Cu—Mg, Cu—Al, Cu—Au, Cu—Pt, Cu—Zr, and Cu—Ti. Furthermore, when the conductive layer 6 is made of a material containing Ag as the major element (50 at % or more), the barrier film 5 can also be used suitably.

In the structure shown in FIG. 1E, the via plug 14 electrically connects the source/drain diffusion layer 11 of the active region and the interconnection portion 13 of the Si substrate 1. Alternatively, the via plug 14 may be used to connect upper and lower two interconnection portions 13 to each other. The combination of the interconnection portion 13 and via plug 14 can be applied to part or entire portion of the multilayered interconnection.

In the manufacturing method shown in FIGS. 1A to 1E, the interconnection portion 13 and via plug 14 are formed by a DD process. This structure can alternatively be formed by a single damascene (SD) process, or by a process in which both of a DD process and SD process are mixed. In the manufacturing method shown in FIGS. 1A to 1E, sputtering is used to form the barrier film 5 and the first conductive film (Cu film). Alternatively, CVD may be used as the film forming method.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an insulating film disposed on or above a semiconductor substrate; and
an interconnection portion disposed on the insulating film,
the interconnection portion comprising
a barrier film disposed on the insulating film, the barrier film including an alloy of a first material and Ta, the first material being at least one element selected from the group consisting of Group IVa elements, Group Va elements excluding Ta, and Group VIa elements, and
a conductive layer disposed on the barrier film, the conductive layer containing Cu or Ag as a major element.

2. A device according to claim 1, wherein the first material is at least one element selected from the group consisting of Nb, Mo, W, and Ti.

3. A device according to claim 2, wherein the first material is an element selected from the group consisting of Nb, Mo, W, and Ti, and a content of the first material in the barrier film is 20 to 90 at % for Nb, 5 to 90 at % for Mo, 10 to 90 at % for W, and 15 to 90 at % for Ti.

4. A device according to claim 1, wherein the alloy consists essentially of a body-centered cubic crystal structure.

5. A device according to claim 1, wherein an interconnection groove is formed in the insulating film, the interconnection portion is buried in the interconnection groove, and the barrier film is disposed on an inner surface of the interconnection groove.

6. A device according to claim 5, wherein a via hole connected to the interconnection groove is formed in the insulating film, a via plug is disposed in the via hole, and the via plug comprises a via barrier film disposed on an inner surface of the via hole and a via conductive layer surrounded by the via barrier film, the via barrier film being made of the same material as that of the barrier film, and the via conductive layer being made of the same material as that of the conductive layer.

7. A device according to claim 1, wherein the barrier film has a thickness of 3 to 30 nm.

8. A device according to claim 1, wherein the first material is Nb, and a Nb content in the barrier film is 20 to 90 at %.

9. A device according to claim 8, wherein the first material is Nb, and a Nb content in the barrier film is 40 to 85 at %.

10. A device according to claim 1, wherein the first material is Mo, and a Mo content in the barrier film is 5 to 90 at %.

11. A device according to claim 1, wherein the barrier film is a product prepared by a process, which includes forming the barrier film on the insulating film by sputtering, and heat-treating the barrier film at a temperature of 350 to 750° C.

12. A device according to claim 1, wherein the barrier film is a product prepared by a process, which includes forming the barrier film on the insulating film by sputtering while heating the semiconductor substrate at a temperature of 150 to 350° C.

13. A device according to claim 1, wherein the conductive layer is a product prepared by a process, which includes forming a first conductive film on the barrier film by sputtering, and forming a second conductive film on the first conductive film by plating.

14. A device according to claim 1, wherein the conductive layer consists essentially of one material selected from the group consisting of Cu, Cu—Ag, Cu—Mg, Cu—Al, Cu—Au, Cu—Pt, Cu—Zr, and Cu—Ti.

15. A device according to claim 1, wherein the insulating film includes silicon oxide containing an organic component.

16. A semiconductor device manufacturing method comprising:
forming an insulating film on or above a semiconductor substrate;
forming an interconnection groove in a surface of the insulating film;
forming a barrier film to cover an inner surface of the interconnection groove, the barrier film including an alloy of a first material and Ta, and the first material being at least one element selected from the group consisting of Group IVa elements, Group Va elements excluding Ta, and Group VIa elements;
forming a conductive layer on the barrier film to fill the interconnection groove, the conductive layer containing Cu or Ag as a major element; and
removing portions of the barrier film and conductive layer, which are located outside the interconnection groove, to form an interconnection portion comprising remainders of the barrier film and conductive layer in the interconnection groove.

17. A method according to claim 16, further comprising:
forming a via hole to be connected to the interconnection groove in the insulating film,
forming the barrier film to cover an inner surface of the via hole, along with the inner surface of the interconnection groove;
forming the conductive layer on the barrier film to fill the via hole, along with the interconnection groove; and
forming a via plug, comprising remainders of the barrier film and conductive layers, in the via hole when forming the interconnection portion.

18. A method according to claim 16, further comprising heat-treating the barrier film at a temperature of 350 to 750° C.

19. A method according to claim 16, further comprising heating the semiconductor substrate at a temperature of 150 to 350° C. when forming the barrier film.

20. A method according to claim 16, wherein the forming a conductive layer includes forming a first conductive film on the barrier film by sputtering, and forming a second conductive film on the first conductive film by plating.
